(19) United States
(12) Patent Application Publication
(10) Pub. No.: US 2014/0116622 A1
(43) Pub. Date: May 1, 2014

(54) ELECTROSTATIC CHUCK AND SUBSTRATE PROCESSING APPARATUS

(71) Applicant: SEMES CO. LTD., Cheonan-si (KR)

(72) Inventor: Won Haeng Lee, Cheonan-si (KR)

(21) Appl. No.: 14/063,023

(22) Filed: Oct. 25, 2013

(30) Foreign Application Priority Data
Oct. 31, 2012 (KR) 10-2012-0122486
Dec. 31, 2012 (KR) 10-2012-0158440

(51) Int. Cl. H01J 37/32; H02N 13/00

(52) U.S. Cl. CPC H01J 37/32715; H02N 13/00
USPC 156/345.51; 361/234

(57) ABSTRACT

Provided is a substrate processing apparatus using plasma. The apparatus includes a chamber having a processing space therein, a substrate supporting assembly located in the chamber and including an electrostatic chuck supporting a substrate, a gas supplying unit supplying gases into the chamber, and a power source applying power for generating plasma from the gases supplied into the chamber. The electrostatic chuck includes a dielectric plate including an electrode adsorbing the substrate by using an electrostatic force, a body located below the dielectric plate and including a metallic plate to which a high frequency power source is connected, and a bonding unit located between the dielectric plate and the body and fastening the dielectric plate and the body. The bonding unit is formed as a multilayer structure.

### CROSS-REFERENCE TO RELATED APPLICATIONS

This U.S. non-provisional patent application claims priority under 35 U.S.C. §119 of Korean Patent Application Nos. 10-2012-0122486, filed on Oct. 31, 2012, and 10-2012-0158440, filed on Dec. 31, 2012, the entire contents of which are hereby incorporated by reference.

### BACKGROUND OF THE INVENTION

The present invention disclosed herein relates to a substrate processing apparatus, and more particularly, to a substrate processing apparatus using plasma.

To manufacture a semiconductor device, various processes such as photolithography, etching, ashing, ion injection, thin film vapor deposition, and cleaning are performed on a substrate to form a desired pattern on the substrate. Among them, an etching process is a process for removing a selected portion of a film formed on a substrate and includes wet etching and dry etching.

To perform the dry etching, an etching apparatus using plasma is used. Generally, to form plasma, electromagnetic fields are formed in an inner space of a chamber and excite processing gases provided into the chamber to a plasma status.

Plasma indicates a status of ionized gas formed of ions, electrons, and radicals. The plasma is generated by very high temperature, strong electric fields, or radio frequency electromagnetic fields. In a process of manufacturing a semiconductor device, an etching process is performed by using plasma. The etching process is performed due to ionic particles contained in the plasma, colliding with a substrate.

Generally, an electrostatic chuck includes a dielectric plate and a metallic body. The dielectric plate and the body are connected to each other by silicon or acryl. Silicon has an excellent heat-resisting property but has a low thermal resistance. Accordingly, the silicon is not damaged by heat generated while processing the substrate. However, the silicon cannot effectively block a transfer of heat between the body and the dielectric plate. The acryl has an excellent thermal resistance. However, heat-resisting property of the acryl is low. The acryl may prevent a thermal loss between the dielectric plate and the body but may be damaged by heat generated while processing the substrate.

### SUMMARY OF THE INVENTION

The present invention provides The present invention provides an electrostatic chuck and a substrate processing apparatus capable of reducing a thermal loss in the electrostatic chuck used in a process of processing a substrate using plasma and having an excellent heat-resisting property.

Embodiments of the present invention provide substrate processing apparatuses including a chamber having a processing space therein, a substrate supporting assembly located in the chamber and including an electrostatic chuck supporting a substrate, a gas supplying unit supplying gases into the chamber, and a power source applying power for generating plasma from the gases supplied into the chamber. The electrostatic chuck includes a dielectric plate including an electrode adsorbing the substrate by using an electrostatic force, a body located below the dielectric plate and including a metallic plate to which a high frequency power source is connected, and a bonding unit located between the dielectric plate and the body and fastening the dielectric plate and the body. The bonding unit is formed as a multilayer structure.

The multilayer structure may include an acryl layer and a silicon layer.

The silicon layer may be located above the acryl layer.

The multilayer structure may further include a bonding intermediate layer provided between the silicon layer and the acryl layer to allow the silicon layer and the acryl layer to be bonded thereto respectively.

The multilayer structure may include a plurality of silicon layers and a bonding intermediate layer provided between the plurality of silicon layers to allow the plurality of silicon layers to be bonded thereto respectively.

The bonding intermediate layer may include ceramic.

The bonding intermediate layer may include quartz.

The bonding intermediate layer may include ceramic.

In other embodiments of the present invention, electrostatic chucks include a dielectric plate including an electrode for adsorbing a substrate by using an electrostatic force, a body located below the dielectric plate and including a metallic plate to which a high frequency power source is connected, and a bonding unit located between the dielectric plate and the body and fastening the dielectric plate and the body. The bonding unit is formed as a multilayer structure.

The multilayer structure may include an acryl layer, a silicon layers and a bonding intermediate layer provided between the silicon layer and the acryl layer to allow the silicon layer and the acryl layer to be bonded thereto respectively.

The silicon layer may be located above the acryl layer.

The multilayer structure may include a plurality of silicon layers and a bonding intermediate layer provided between the plurality of silicon layers to allow the plurality of silicon layers to be bonded thereto respectively.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a cross-sectional view illustrating a substrate processing apparatus according to an embodiment of the present invention;

FIG. 2 is an enlarged view illustrating an example of a bonding unit used in an electrostatic chuck of FIG. 1; and

FIG. 3 is a view illustrating another example of the bonding unit of FIG. 2.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

Accordingly, shapes of elements in the drawings are exaggerated for clearer explanation.

Hereinafter, the embodiments of the present invention will be described in detail with reference to the attached drawings. The embodiments of the present invention may be modified into various forms, and the scope of the present invention is not limited to the following embodiments. The embodiments are provided to more perfectly explain the present invention to a person with ordinary skill in the art. Accordingly, shapes of elements in the drawings are exaggerated for more accurate descriptions.

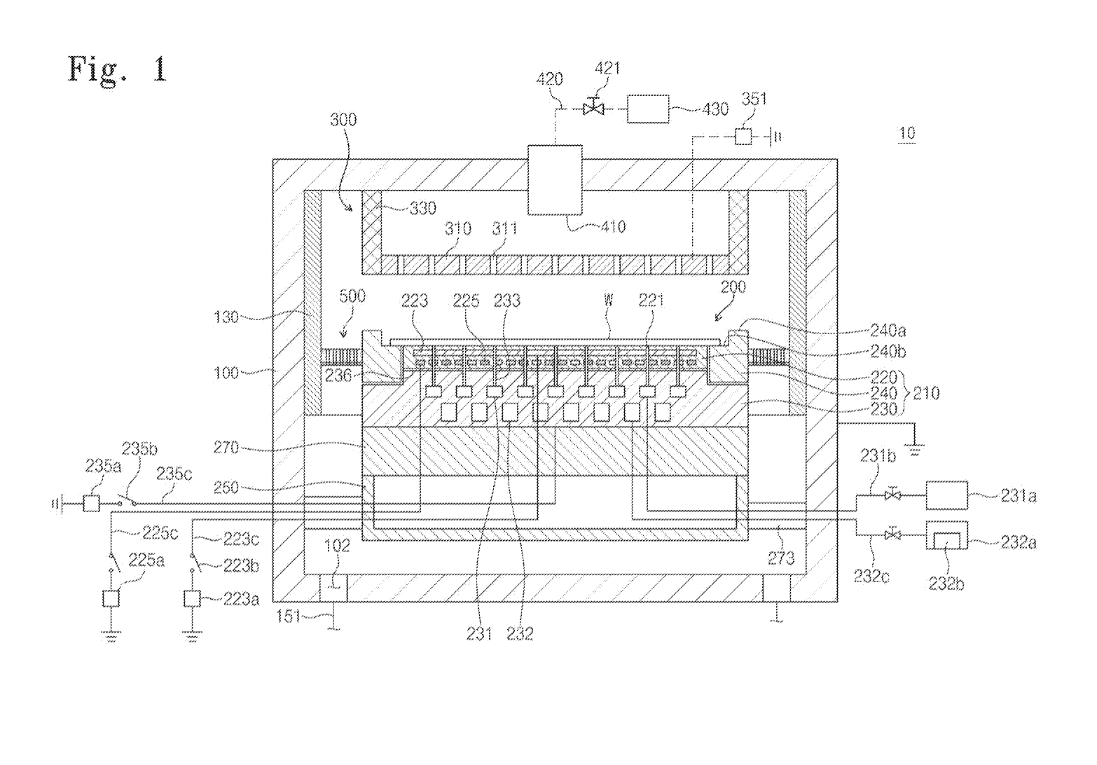

FIG. 1 is a cross-sectional view illustrating a substrate processing apparatus 10 according to an embodiment of the present invention.

Referring to FIG. 1, the substrate processing apparatus 10 processes a substrate W by using plasma. For example, the substrate processing apparatus 10 may perform an etching process on the substrate W. The substrate processing apparatus 10 includes a chamber 100, a substrate supporting assembly 200, a shower head 300, a gas supplying unit 400, a plasma source, and a baffle unit 500.

The chamber 100 provides a processing space in which a substrate processing process is performed. The chamber 100 is provided as a sealed shape having the processing space therein. The chamber 100 is formed of a metallic material. The chamber 100 may be formed of aluminum. The chamber 100 may be grounded. An exhaustion hole 102 is formed in a bottom surface of the chamber 100. The exhaust hole 102 is connected to an exhaustion line 151. By-products generated in the processing process and gases remaining in an inner space of the chamber 100 may be discharged outward through the exhaustion line 151. The inside of the chamber 100 is depressurized to a certain degree of pressure by an exhaustion process.

As an example, a liner 130 may be provided in the chamber 100. The liner 130 has the shape of a cylinder with open top and bottom. The liner 130 may be in contact with an inner surface of the chamber 100. The liner 130 protects an inner wall of the chamber 100 and prevents the inner wall of the chamber 100 from being damaged by arc discharges. Also, it is prevented that impurities generated during the substrate processing process are vapor-deposited on the inner wall of the chamber 100. Selectively, the liner 130 may not be provided.

The substrate supporting assembly 200 is located in the chamber 100. The substrate supporting assembly 200 supports the substrate W. The substrate supporting assembly 200 may include an electrostatic chuck 210 adsorbing the substrate W using an electrostatic force. Differently, the substrate supporting assembly 200 may support the substrate W using various methods such as mechanical clamping. Hereinafter, the substrate supporting assembly 200 including the electrostatic chuck 210 will be described.

The substrate supporting assembly 200 includes the electrostatic chuck 210, a lower cover 250, and a plate 270. The substrate supporting assembly 200 is located in the chamber 100 to be separated upward from the bottom surface of the chamber 100.

The electrostatic chuck 210 includes a dielectric plate 220, a body 230, and a focus ring 240. The electrostatic chuck 210 supports the substrate W.

The dielectric plate 220 is located on a top of the electrostatic chuck 210. The dielectric plate 220 is provided as a circular plate formed of a dielectric substance. The substrate W is disposed on a top surface of the dielectric plate 220. A top surface of the dielectric plate 220 has a radius smaller than that of the substrate W. Accordingly, an edge portion of the substrate W is located outside the dielectric plate 220.

The dielectric plate 220 includes a first electrode 223, a heater 225, and a first supplying flow channel 221 thereinside. The first supplying flow channel 221 is provided from the top surface to a bottom surface of the dielectric plate 220. The first supplying flow channel 221 is formed in plurality thereof separated from one another and is provided as a path for supplying a heat transfer medium to a bottom surface of the substrate W.

The first electrode 223 is electrically connected to a first power source 223a. The first power source 223a includes a direct current power source. A switch 223b is installed between the first electrode 223 and the first power source 223a. The first electrode 223 may be electrically connected to the first power source 223a, depending on turning on/off the switch 223b. When the switch 223b is turned on, a direct current is applied to the first electrode 223. An electrostatic force acts between the first electrode 223 and the substrate W due to the current applied to the first electrode 223. The substrate W is adsorbed onto the dielectric plate 220 due to the electrostatic force.

The heater 225 is located below the first electrode 223. The heater 225 is electrically connected to a second power source 225a. The heater 225 resists currents applied from the second power source 225a, thereby generating heat. The generated heat is transferred to the substrate W through the dielectric plate 220. The heat generated by the heater 225 maintains the substrate W at a certain temperature. The heater 225 includes a spiral-shaped coil.

The body 230 is located below the dielectric plate 220. The bottom surface of the dielectric plate 220 and a top surface of the body 230 may be bonded by a bonding unit 236. The body 230 may be formed of aluminum. The top surface of the body 230 may be tiered to allow a central portion to be located higher than an edge portion. The central portion of the top surface of the body 230 has an area corresponding to the bottom surface of the dielectric plate 220 and is bonded to the bottom surface of the dielectric plate 220. The body 230 includes a first circulation flow channel 231, a second circulation flow channel 232, and a second supplying flow channel 233 formed therein.

The first circulation flow channel 231 is provided as a path through the heat transfer medium circulates. The first circulation flow channel 231 may be formed as a spiral shape in the body 230. Alternatively, the first circulation flow channel 231 may be disposed in such a way that flow channels having a ring shape and mutually different radiuses have the same center. The respective first circulation flow channels 231 may be connected to one another. The first circulation flow channels 231 are formed to be flush with one another.

The second circulation flow channel 232 is provided as a path through a cooling fluid circulates. The second circulation flow channel 232 may be formed as a spiral shape in the body 230. Alternatively, the second circulation flow channel 232 may be disposed in such a way that flow channels having a ring shape and mutually different radiuses have the same center. The respective second circulation flow channels 232 may be connected to one another. The second circulation flow channel 232 may have a larger cross section than the first circulation flow channel 231. The second circulation flow channels 232 are formed to be flush with one another. The second circulation flow channel 232 may be located below the first circulation flow channel 231.

The second supplying flow channel 233 is extended upwardly from the first circulation flow channel 231 and is provided to the top surface of the body 230. The second supplying flow channel 243 is provided as a number corresponding to the first supplying flow channel 221 and connects the first circulation flow channel 231 with the first supplying flow channel 221.

The first circulation flow channel 231 is connected to a heat transfer medium storage unit 231a through a heat transfer medium supplying line 231b. The heat transfer medium storage unit 231a stores the heat transfer medium. The heat transfer medium includes inert gases. According to embodiments, the heat transfer medium includes helium gas. The helium gas is supplied to the first circulation flow channel 231 through the heat transfer medium supplying line 231b, sequentially passes through the second supplying flow channel 233 and the first supplying flow channel 221, and is supplied to the bottom surface of the substrate W. The helium gas functions as a medium for transferring heat transferred from the plasma to the substrate W to the electrostatic chuck 210.

The second circulation flow channel 232 is connected to a cooling fluid storage unit 232a through a cooling fluid supplying line 232c. The cooling fluid storage unit 232a stores the cooling fluid. The cooling fluid storage unit 232a may include a cooler 232b provided therein. The cooler 232b cools down the cooling fluid to a certain temperature. Differently, the cooler 232b may be installed on the cooling fluid supplying line 232c. The cooling fluid supplied to the second circulation flow channel 232 through the cooling fluid supplying line 232c circulates through the second circulation flow channel 232 and cools down the body 230. The body 230 is cooled down and cools down the dielectric plate 220 and the substrate W together, thereby maintaining the substrate W at a certain temperature.

The body 230 may include a metallic plate. As an example, the entire body 230 may be formed of the metallic plate. The Body 230 may be electrically connected to a third power source 235a. The third power source 235a may be provided as a high frequency power source for generating high frequency power. The high frequency power source may be provided as a radio frequency (RF) power source. The body 230 receives radio frequency power from the third power source 235a. Due thereto, the body 230 may function as an electrode.

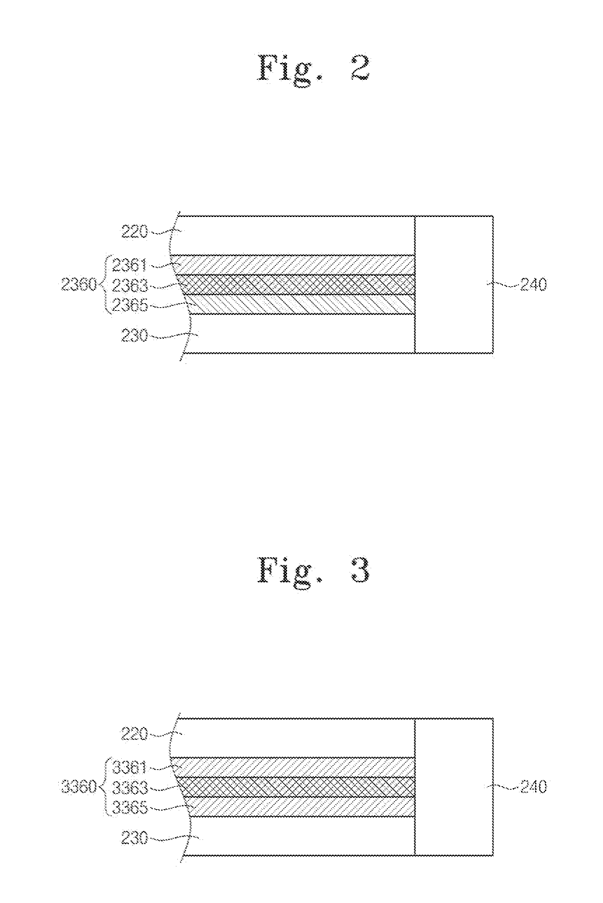

FIG. 2 is an enlarged view illustrating an example of the bonding unit 236 used in the electrostatic chuck 210 of FIG. 1.

Referring to FIG. 2, the bonding unit 2360 is located between the dielectric plate 220 and the body 230. The bonding unit 2360 is bonded to the dielectric plate 220 and the body 230, respectively. As an example, the bonding unit 2360 is provided as a multilayer structure. The bonding unit 2360 may include a silicon layer 2361 and an acryl layer 2365. The silicon layer 2361 may be located above the acryl layer 2365.

A bonding intermediate layer 2363 may be provided between the silicon layer 2361 and the acryl layer 2365. The silicon layer 2361 and the acryl layer 2365 are not well bonded to each other. The bonding intermediate layer 2363 is bonded to the silicon layer 2361 and the acryl layer 2365, respectively. Through this, the multilayer structure of the bonding unit 2360 may be maintained. The bonding intermediate layer 2363 is formed of a material to be well bonded to ceramic and silicon. As an example, the bonding intermediate layer 2363 may be formed of one of ceramic, quartz, and a metallic material.

FIG. 3 is a view illustrating another example of the bonding unit 2360.

Referring to FIG. 3, a bonding unit 3360 is located between the dielectric plate 220 and the body 230. The bonding unit 3360 is bonded to the dielectric plate 220 and the body 230, respectively. As an example, the bonding unit 3360 is provided as a multilayer structure. The bonding unit 3360 may include a plurality of silicon layers 3361.

A bonding intermediate layer 3363 is provided between the plurality of silicon layers 3361. Silicon has an excellent heat-resisting property but has a low thermal resistance. When providing the silicon having a great thickness, it is possible to provide a certain thermal resistance. However, the silicon is difficult to be provided greater than a certain thickness. As an example, the silicon layer 3361 is provided in plurality thereof. The bonding intermediate layer 3363 is provided between the plurality of silicon layers 3361. By using a method as described above, the bonding unit 3360 having a preset thermal resistance may be provided. As an example, the bonding intermediate layer 3363 may be formed of one of ceramic, quartz, and a metallic material.

In the embodiments and modifications described above, the bonding unit 3360 is provided as a multilayer structure having three layers. However, the multilayer structure may have more than three layers.

The focus ring 240 is disposed in an edge portion of the electrostatic chuck 210. The focus ring 240 has a ring shape and is disposed along a circumference of the dielectric plate 220. A top surface of the focus ring 240 may be tired to allow an outer portion 240a to be higher than an inner portion 240b. The inner portion 240b of the top surface of the focus ring 240 is located to be flush with the top surface of the dielectric plate 220. The inner portion 240b of the top surface of the focus ring 240 supports the edge portion of the substrate W located outside the dielectric plate 220. The outer portion 240a of the focus ring 240 may be provided to surround the edge portion of the substrate W. The focus ring 240 controls an electromagnetic field to allow density of plasma to be uniformly distributed in the entire area of the substrate W. Due to this, plasma is uniformly formed over the entire area of the substrate W, thereby uniformly etching each area of the substrate W.

The lower cover 250 is located on a bottom end of the substrate supporting assembly 200. The lower cover 250 is separated upwardly from the bottom surface of the chamber 100. A space with open top is formed in the lower cover 250. An outer radius of the lower cover 250 may be provided as the same length as an outer radius of the body 230. In the space in the lower cover 250, a lift pin module (not shown) and the like may be located to transfer the substrate W from an external transfer element to the electromagnetic chuck 210 may be located. A bottom surface of the lower cover 250 may be formed of a metallic material.

The lower cover 250 includes a connection element 253. The connection element 253 connects an outer surface of the lower cover 250 with the inner wall of the chamber 100. A plurality of the connection element 253 may be provided on the outer surface of the lower cover 250 with certain intervals. The connection element 253 supports the substrate supporting assembly 200 in the chamber 100. Also, the connection element 253 is connected to the inner wall of the chamber 100, thereby allowing the lower cover 250 to be electrically grounded. A first power source line 223c connected to the first power source 223a, a second power source line 225c connected to the second power source 225a, a third power source line 235c connected to the third power source 235a, the heat transfer medium supplying line 231b connected to the heat transfer medium storage unit 231a, and the cooling fluid supplying line 232c connected to the cooling fluid storage unit 232a are extended toward the inside of the lower cover 250 through an inner space of the connection element 253.

The plate 270 is located between the electrostatic chuck 210 and the lower cover 250. The plate 270 covers a top surface of the lower cover 250. The plate 270 is provided as a cross-sectional area corresponding to the body 230. The plate 270 may include an insulator. The plate 270 electrically insulates the body 230 and the lower cover 250 form each other.

The shower head 300 is located above the substrate supporting assembly 200 in the chamber 100. The shower head 300 is located to face the substrate supporting assembly 200.

The shower head 300 includes a gas diffuser 310 and a supporter 330. The gas diffuser 310 is located to be separated from a top surface of the chamber 100 with a certain distance. A certain space is formed between the gas diffuser 310 and the top surface of the chamber 100. The gas diffuser 310 may be provided as a plate with a certain thickness. A bottom surface of the gas diffuser 310 may be polarized to prevent arcs occurring due to plasma. A cross section of the gas diffuser 310 may be provided to have the same shape and cross-sectional area as the substrate supporting assembly 200. The gas diffuser 310 includes a plurality of diffusion holes 311. The diffusion holes 311 perpendicularly penetrate a top surface to the bottom surface of the gas diffuser 310. The gas diffuser 310 includes a metallic material. The gas diffuser 310 may be electrically connected to a fourth power source 351. The fourth power source 351 may be provided as a high frequency power source. Differently, the gas diffuser 310 may be electrically grounded. The gas diffuser 310 may be electrically connected to the fourth power source 351 or may be grounded to function as an electrode.

The supporter 330 supports sides of the gas diffuser 310. A top end of the supporter 330 is connected to the top surface of the chamber 100 and a bottom end thereof is connected to the sides of the gas diffuser 310. The supporter 330 may include a nonmetallic material.

The gas supplying unit 400 supplies a processing gas into the chamber 100. The gas supplying unit 400 includes a gas supplying nozzle 410, a gas supplying line 420, and a gas storage part 430. The gas supplying nozzle 410 is installed in a central portion of the top surface of the chamber 100. An injection hole is formed in a bottom surface of the gas supplying nozzle 410. The injection hole supplies the processing gas into the chamber 100. The gas supplying line 420 connects the gas supplying nozzle 410 with the gas storage part 430. The gas supplying line 420 supplies the processing gas stored in the gas storage part 430 to the gas supplying nozzle 410. A valve 421 is installed on the gas supplying line 420. The valve 421 opens and closes the gas supplying line 420 and controls a flow of the processing gas supplied through the gas supplying line 420.

A plasma source excites the processing gas in the chamber 100 to a plasma status. In the present embodiment, capacitively coupled plasma (CCP) is used as the plasma source. The CCP may include an upper electrode and a lower electrode in the chamber 100. The upper electrode and the lower electrode may be disposed perpendicularly in parallel with each other in the chamber 100. High frequency power may be applied to one of the both electrodes and another thereof may be grounded. An electromagnetic field is formed in a space between the both electrodes. The processing gas supplied to the space may be excited to be in a plasma status. A substrate processing process is performed by using the plasma. As an example, the upper electrode is provided as the shower head 300 and the lower electrode may be provided as the body 230. High frequency power may be applied to the lower electrode, and the upper electrode may be grounded. Differently, high frequency power may be applied to both the upper electrode and lower electrode. Due thereto, an electromagnetic field is generated between the upper electrode and the lower electrode. The generated electromagnetic field excites the processing gas provided into the chamber 100 to a plasma status.

The baffle unit 500 is located between the inner wall of the chamber 100 and the substrate supporting assembly 200. A baffle 510 is formed as a ring shape. The baffle 510 includes a plurality of penetration holes 511 formed therein. The processing gas provided into the chamber 100 passes through the penetration holes 511 of the baffle 510 and is exhausted through the exhaustion hole 102. A flow of the processing gas may be controlled according to a shape of the baffle 510 and respective shapes of the penetration holes 511.

Hereinafter, a process of processing the substrate W by using the substrate processing apparatus 10 will be described.

When disposing the substrate W on the substrate supporting assembly 200, direct currents are applied from the first power source 223a to the first electrode 223. An electrostatic force acts between the first electrode 223 and the substrate W due to the direct currents applied to the first electrode 223. The substrate W is adsorbed onto the electromagnetic chuck 210 due to the electrostatic force.

When the substrate W is adsorbed onto the electromagnetic chuck 210, the processing gas is supplied into the chamber 100 through the gas supplying nozzle 410. The processing gas is uniformly diffused into the chamber 100 through the diffusion hole 311 of the shower head 300. The high frequency power generated by the third power source 235a is applied to the body 230 provided as the lower electrode. The diffuser 310 of the shower head 300, provided as the upper electrode, is grounded. An electromagnetic force is generated between the upper electrode and the lower electrode. The electromagnetic force excites the processing gas between the substrate supporting assembly 200 and the shower head 300 to be plasma. The plasma is provided to the substrate W to process the same. The plasma may perform an etching process.

The electrostatic chuck 210 is formed by bonding the dielectric plate 220 to the body 230 by using the bonding unit 2360. The bonding unit 2360 is formed as a multilayer structure. The bonding unit 2360 includes the silicon layer 2361 and the acryl layer 2365. The silicon layer has an excellent heat-resisting property, and the acryl layer has an excellent thermal resistance. Through this, the bonding unit 2360 may have both the heat-resisting property and thermal resistance. The bonding unit 2360 may reduce a thermal loss generated in the dielectric plate 220. Due thereto, efficiency of the substrate processing process may be improved.

According to the embodiments, it is possible to provide an electrostatic chuck for reducing a thermal loss in the electrostatic chuck used in a substrate processing process using plasma and having an excellent heat-resisting property and a substrate processing apparatus.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A substrate processing apparatus comprising:
a chamber having a processing space therein;
a substrate supporting assembly located in the chamber and comprising an electrostatic chuck supporting a substrate;
a gas supplying unit supplying gases into the chamber; and
a power source applying power for generating plasma from the gases supplied into the chamber,
wherein the electrostatic chuck comprises:
a dielectric plate comprising an electrode adsorbing the substrate by using an electrostatic force;
a body located below the dielectric plate and comprising a metallic plate to which a high frequency power source is connected; and
a bonding unit located between the dielectric plate and the body and fastening the dielectric plate and the body,
wherein the bonding unit is formed as a multilayer structure.

2. The apparatus of claim 1, wherein the multilayer structure comprises an acryl layer and a silicon layer.

3. The apparatus of claim 2, wherein the silicon layer is located above the acryl layer.

4. The apparatus of claim 3, wherein the multilayer structure further comprises a bonding intermediate layer provided between the silicon layer and the acryl layer to allow the silicon layer and the acryl layer to be bonded thereto respectively.

5. The apparatus of claim 1, wherein the multilayer structure comprises a plurality of silicon layers and a bonding intermediate layer provided between the plurality of silicon layers to allow the plurality of silicon layers to be bonded thereto respectively.

6. The apparatus according to claim 4, wherein the bonding intermediate layer comprises ceramic.

7. The apparatus according to claim 4, wherein the bonding intermediate layer comprises quartz.

8. The apparatus according to claim 4, wherein the bonding intermediate layer comprises metal.

9. An electrostatic chuck comprising:
a dielectric plate comprising an electrode for adsorbing a substrate by using an electrostatic force;
a body located below the dielectric plate and comprising a metallic plate to which a high frequency power source is connected; and
a bonding unit located between the dielectric plate and the body and fastening the dielectric plate and the body,
wherein the bonding unit is formed as a multilayer structure.

10. The electrostatic chuck of claim 9, wherein the multilayer structure comprises an acryl layer, a silicon layers and a bonding intermediate layer provided between the silicon layer and the acryl layer to allow the silicon layer and the acryl layer to be bonded thereto respectively.

11. The electrostatic chuck of claim 10, wherein the silicon layer is located above the acryl layer.

12. The electrostatic chuck of claim 9, wherein the multilayer structure comprises a plurality of silicon layers and a bonding intermediate layer provided between the plurality of silicon layers to allow the plurality of silicon layers to be bonded thereto respectively.

13. The electrostatic chuck of claim 9, wherein the multilayer structure comprises a first bonding layer and a second bonding layer,
wherein the first bonding layer is formed of a material having a more excellent heat-resisting property than the second bonding layer, and
wherein the second bonding layer is formed of a material having a more excellent thermal resistance than the first bonding layer.

14. The electrostatic chuck of claim 13, wherein the first bonding layer is located below the second bonding layer.

15. The electrostatic chuck of claim 14, wherein the multilayer structure comprises a bonding intermediate layer provided between the first bonding layer and the second bonding layer to allow the first bonding layer and the second bonding layer to be bonded thereto respectively.

16. The electrostatic chuck according to claim 10, wherein the bonding intermediate layer comprises ceramic.

17. The electrostatic chuck according to claim 10, wherein the bonding intermediate layer comprises quartz.

18. The electrostatic chuck according to claim 10, wherein the bonding intermediate layer comprises metal.
